(19) United States
(12) Patent Application Publication
(10) Pub. No.: US 2006/0024445 A1
(43) Pub. Date: Feb. 2, 2006

(54) Extrusion coating system

(75) Inventors: Alfred H. Willnow, Ontario, NY (US); Kent J. Evans, Lima, NY (US); Colleen A. Helbig, Penfield, NY (US); Kathleen M. Carmichael, Williamson, NY (US); June E. Schneider, Honeoye Falls, NY (US); David M. Skinner, Rochester, NY (US); Min-Hong Fu, Webster, NY (US); Walter H. Lerminiaux JR., Ontario, NY (US); Mark Muscato, Webster, NY (US); Kenneth M. Strong, Hilton, NY (US); David A. DeHollander, Fairport, NY (US); Kirk W. Michaels, Penfield, NY (US)

Correspondence Address: Richard M. Klein, Esq.;FAY, SHARPE, FAGAN, MINNICH & McKEE, LLP, SEVENTH FLOOR, 1100 SUPERIOR AVENUE, CLEVELAND, OH, 44114-2579, US

(73) Assignee: Xerox Corporation

(21) Appl. No.: 10/901,322

(22) Filed: Jul. 28, 2004

(51) Int. Cl. B05D 3/12; B05D 3/00; C23C 14/00

(52) U.S. Cl. 427/294; 427/356; 118/50; 118/400

(57) ABSTRACT

A coating application system includes a coating applicator having an outlet through which a stream of a liquid coating is delivered, a substrate which receives the stream of liquid coating, and a vacuum system which applies a vacuum to the liquid coating.

### BACKGROUND

The present disclosure generally relates to the application of a coating composition to a substrate. In certain embodiments, it finds particular application in conjunction with vacuum assisted extrusion coating of flexible substrates, such as photoreceptor belts, and will be described with particular reference thereto. However, it is to be appreciated that the present disclosure is also amenable to other like applications.

Electrophotographic imaging members, such as multilayered photoreceptor belts, can comprise a substrate, which supports several layers. U.S. Pat. No. 6,645,686 (Fu, et al.), the disclosure of which is incorporated herein in its entirety, by reference, discloses one type of multi-layered photoreceptor that has been employed as a belt in electrophotographic imaging systems. The photoreceptor belt comprises a substrate, an electrically conductive surface layer, a charge blocking layer, a charge generating layer, and a charge transport layer. The multi-layered type of photoreceptor may also comprise additional layers, such as an anti-curl backing layer, which is beneficial when layers possess different coefficient of thermal expansion values, an adhesive layer, and an overcoating layer.

The various layers of a photoreceptor are deposited in sequence. The electrically conductive surface layer may be a metal layer formed, for example, on the support layer by a coating technique, such as a vacuum deposition. Typical metals employed for this purpose include aluminum, zirconium, niobium, tantalum, vanadium hafnium, titanium, nickel, stainless steel, chromium, tungsten, molybdenum, alloys and oxides thereof, and the like. Another material suitable for forming the surface layer is conductive carbon black dispersed in a plastic binder.

After deposition of an electrically conductive surface layer, the blocking layer may be applied thereto. Generally, blocking layers for positively charged photoreceptors allow holes from the imaging surface of the photoreceptor to migrate toward the conductive layer. Typical blocking layers include polyvinylbutyral, organosilanes, epoxy resins, polyesters, polyamides, polyurethanes, fluorocarbon resins, silicone resins, and the like containing an organo-metallic salt. For example, the blocking layer may comprise a reaction product between a hydrolyzed silane and a thin metal oxide layer formed on an outer surface of an oxidizable metal electrically conductive surface.

An adhesive layer may be applied to the blocking layer or directly to the conductive surface where no blocking layer is used. Typical adhesive layers include a polyester resin, such as VITEL PE-100™, VITEL PE-200 ™, VITEL PE-200D™, or VITEL PE-222 ™, all from Bostik, or a polyarylate, such as ARDEL POLYARYLATE (U-100) from Yuniehkia. The adhesive layer is continuous and generally has an average dry thickness of from about 200 Angstroms to about 1200 Angstroms. The adhesive layer is laid down as a coating solution comprising a suitable solvent or solvent mixture and the adhesive layer material. Typical solvents include tetrahydrofuran, toluene, methylene chloride, cyclohexanone, chlorobenzene, and mixtures thereof.

In a multi-layer photoreceptor, a charge generating layer is applied to the adhesive layer, where employed. A charge transport layer is applied to the charge generating layer. In a single layer photoreceptor, a combined charge generating and charge transport layer is applied to the adhesive layer, where employed. Examples of materials for the charge generating layer include inorganic photoconductive particles, such as amorphous selenium, trigonal selenium, selenium alloys, and organic photoconductive particles including various phthalocyanine pigments.

The charge transport layer often comprises an activating small molecule dispersed or dissolved in a polymeric film forming binder. The polymeric film forming binder in the transport layer is electrically inactive by itself and becomes electrically active when it contains the activating molecule. The electrically active material is capable of supporting the injection of photogenerated charge carriers from the material in the charge generating layer and is capable of allowing the transport of these charge carriers through the electrically active layer in order to discharge a surface charge on the active layer. An overcoat layer may also be deposited over the charge transport layer to improve durability, etc.

The anti-curl back coating layers may comprise thermoplastic organic polymers or inorganic polymers that are electrically insulating or slightly semi-conductive. A suitable film forming thermoplastic resin soluble in methylene chloride or other suitable solvent may be employed in the anticurl backing layer. Typical film forming resins include polycarbonate resin, polyvinylcarbazole, polyester, and polyarylate.

Numerous techniques have been devised to form a layer of a coating composition on a substrate, including spraying, dip coating, draw bar coating, gravure coating, silk screening, extrusion coating, and the like. To achieve a thin coating, such as the adhesive layer of a multilayered photoreceptor, gravure coating techniques are often used.

In a gravure process, the coating, such as the adhesive coating, is applied via an intermediate coating drum. However, accurate and consistent thickness control is difficult to achieve. Thickness is determined by the gravure cell pattern and the solution solids level, which are not readily adjusted during a coating process. As a result, the product formed may have sections which do not meet specifications and thus are discarded. Additionally, the coating solution is partially exposed to the atmosphere, which can result in solvent evaporation and changes in the solids level. Consistent thickness control from roll to roll is thus difficult to achieve due to variations in solvent evaporation rates.

Extrusion techniques for forming thin layers of dispersion coatings are known and described, for example in U.S. Pat. No. 4,521,457 (Russell, et al.), U.S. Pat. No. 5,516,557 (Willnow, et al.), U.S. Pat. No. 5,614,260 (Darcy), and U.S. Pat. No. 6,057,000 (Cai), the entire disclosures thereof being incorporated herein by reference. Typical extrusion techniques include, for example, slot coating, slide coating, curtain coating, and the like. For fabrication of web type, flexible electrophotographic imaging members, the extrusion die lays down a thin coating. During the extrusion or slot coating of thin layers, the window of operating parameters is extremely small and is affected by factors such as coating thickness, speed of substrate, rheological properties of the coating liquids, vacuum pressure, relative speed of the ribbon of coating material, pressure applied to the coating material as it progresses through an extrusion nozzle, and the like.

The extrusion die usually includes spaced, walls or lands, each having a flat surface parallel to and facing the other. These spaced lands form a narrow, elongated, extrusion passageway having an entrance at one end and an exit slot at the opposite end of the passageway. The passageway normally has side walls to direct the flow of a thin ribbon shaped stream of coating composition. Generally, the coating composition is supplied by a manifold positioned along the length of the entrance of the extrusion passageway. The liquid coating composition travels from a pump and through a feed channel, such as a pipe, to the manifold of the extrusion die. The liquid coating composition is distributed by the manifold into the entrance of the extrusion passageway. The liquid coating composition then travels through the extrusion passageway and out of the exit slot as a ribbon-like extrudate and is deposited onto a substrate to be coated. After various layers are deposited, the coated photoreceptor web is subsequently sliced to form rectangular sheets which are each formed into a belt type photoreceptor by welding opposite ends of the sheet together.

A typical photoreceptor extrusion die manifold has a cavity in the shape of a cylinder having with a constant cross sectional area from one end of the cavity to the opposite end. U.S. Pat. No. 6,057,000 describes alternative manifold configurations having progressively narrowing channels.

U.S. Pat. No. 6,214,513 (Cai, et al.) discloses a coating process for the fabrication of organic photoreceptors which employs an electrically conductive single slot die biased to allow an electric field between the die and a ground plane on the photoreceptor substrate. A homogenous coating dispersion is fed through the die at a predetermined gap and rate to control coating thickness at the same time that an electric field is applied.

The use of conventional extrusion slot die methods of forming thin coatings of dispersions of photoconductive particles can produce defects resembling brush marks along each edge of the deposited coating. These brush marks can remain as defects in the dried coating and can ultimately print out as undesirable artifacts in the final electrophotographic copy.

There remains a need for a more accurate and consistent system which is capable of applying thin coating layers, such as an adhesion layer, to a substrate, such as a flexible belt, web, etc.

### BRIEF DESCRIPTION

The present disclosure is generally directed to a coating application system for applying a thin, uniform coating of a composition to a substrate. In one embodiment, it relates to the application of a coating composition to a flexible substrate through the use of a vacuum assisted extrusion process. This system can be utilized to produce multi-layered photoreceptor belts.

In another embodiment, the disclosure concerns a coating application system for applying thin coating layers to a moving substrate, such as a flexible belt, web, etc. The coating application system utilizes a vacuum assisted extrusion process. The system is particularly well suited for the formation of an adhesive interface layer of a photoreceptor, such as an active matrix (AMAT) photoreceptor.

In a further embodiment, a coating application system is provided for applying an adhesive coating to a photoreceptor substrate. The coating application system includes a coating applicator having an outlet through which a stream of an adhesive liquid coating is delivered to a photoreceptor substrate. Also included is a vacuum system which applies a vacuum to the adhesive liquid coating during delivery to form a thin and uniform layer.

In still another aspect, the disclosure concerns a coating application system for applying an adhesive layer to a flexible substrate of an electrophotographic imaging member. The system includes a coating application having an outlet through which a stream of a liquid adhesive coating is delivered, a means for supporting an associated moving substrate a spaced distance from the outlet, and a vacuum system which applies a vacuum to the liquid adhesive coating during the delivery process.

These and other non-limiting aspects and/or objects of the disclosure are more particularly described below.

### BRIEF DESCRIPTION OF THE DRAWINGS

The following is a brief description of the drawings, which are presented for the purposes of illustrating the development disclosed herein and not for the purposes of limiting the same.

FIG. 1 is a side sectional view of a coating application system according to the present disclosure; and

FIG. 2 is a perspective view of the coating application system of FIG. 1 with an upper body portion of an extrusion die removed for clarity.

### DETAILED DESCRIPTION

The present disclosure is directed to a system for applying a coating, such as an adhesive coating, to a substrate to produce a photoreceptor, such as a multi-layered photoreceptor belt. In this regard, the coating application system may include an extrusion coating applicator, such as an extrusion dye, which extrudes a ribbon-shaped stream of a coating liquid, such as that comprising an adhesive composition. A moving substrate receives the stream. A vacuum system applies a vacuum to the stream as it is received by the substrate. Among other characteristics, the improved coating application system allows the production of uniform coating(s) while allowing a broad coating latitude.

The present disclosure is also directed to a method for the deposition of a thin coating, such as an adhesive coating, on a moving substrate. The substrate may be a flexible substrate including flexible belts, webs, etc. A ribbon-shaped stream of coating liquid is thinly applied to a substrate. A vacuum is applied to the coating liquid during application to enhance coating stability allowing for thinner layers to be applied.

A more complete understanding of the processes and apparatuses disclosed herein can be obtained by reference to the accompanying drawings. These figures are merely schematic representations based on convenience and the ease of demonstrating the existing art and/or the present development, and are, therefore, not intended to indicate relative size and dimensions of the assemblies or components thereof.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to component of like function.

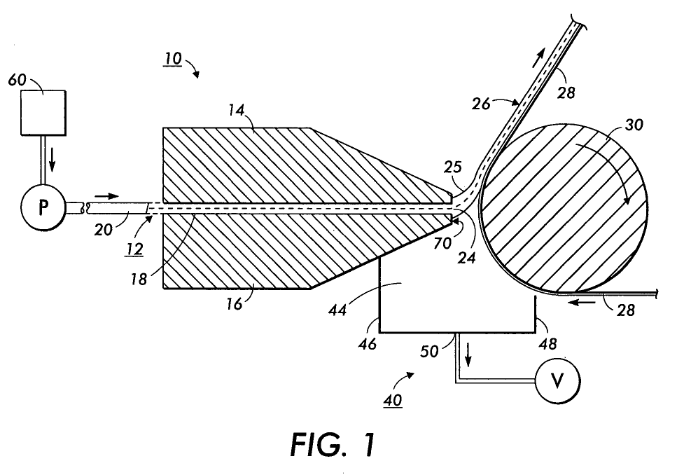

With reference to the FIGURES, wherein like reference numerals are used to denote like or analogous components throughout both views, FIG. 1 shows an exemplary extrusion coating applicator comprising a die assembly 10. Extrusion dies are well known and described, for example, in U.S. Pat. Nos. 4,521,457, 5,614,260, and 6,057,000, the entire disclosures thereof being incorporated herein by reference. Die assembly 10 includes a die body 12 equipped with suitable clamping members, such as flanges (not shown), such as those illustrated in U.S. Pat. No. 4,521,457.

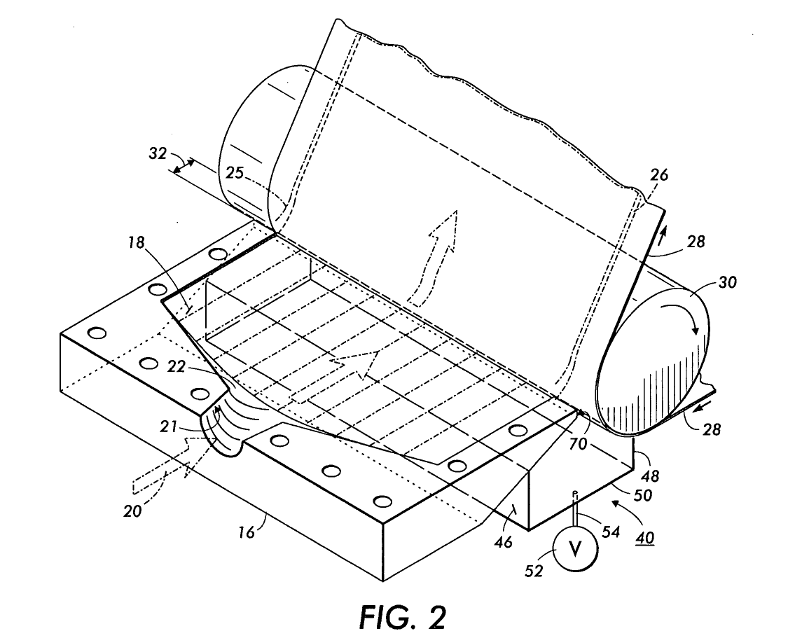

The die body 12 includes an upper body 14 and a lower body 16, which are spaced apart to form a flat, narrow passageway 18 (see FIG. 2). Any suitable means such as screws, bolts, studs, or clamps (not shown) or the like, may be utilized to fasten the upper body 14 and the lower body 16 together. The passageway 18 is fed with a liquid coating composition which enters the die body 12 through an inlet 20 of a feed channel 21 and is transported through a manifold 22 to the passageway 18. The liquid coating exits the passageway 18 through an exit slot 24. The manifold 22 can be cylindrical in cross section or progressively narrow, away from the feed channel 21, as shown in U.S. Pat. No. 6,057,000 and illustrated in FIG. 2. The coating composition is extruded from the exit slot 24 as a ribbon-like stream 25 and deposited as a coating 26 on a moving substrate 28, such as a flexible web or belt. The substrate 28 is supported on a rotating support member, such as a cylindrical backing roll 30, as the substrate passes the exit slot 24.

The width, thickness, and the like of the ribbon-like stream 25 can be varied in accordance with factors such as the viscosity of the coating composition, thickness of the coating desired, and width of the web substrate on which the coating composition is applied, and the like.

The length of passageway 18 is sufficiently long to also ensure laminar (or streamline) flow. Control of a distance 32 of the exit slot 24 from the substrate 28 to be coated enables the coating composition to bridge the gap between the exit slot 24 and the moving substrate 28 depending upon the viscosity, coating thickness, and rate of flow of the coating composition 25. Generally, it is preferred to position the exit slot 24 for lower viscosity ribbon-like streams closer to the substrate 28 than for wider extrusion slot outlets for higher viscosity ribbon-like streams, to allow formation of a bead 34 of coating material which functions as a reservoir for greater control of coating deposition.

A vacuum system 40 applies a vacuum to the coating liquid 25 as it bridges the gap 32 between the exit slot 24 and the substrate 28. In particular, the vacuum is applied to the coating bead 34 at the upstream end of the applied coating composition 26. The vacuum system 40 includes a housing or vacuum box 42 which defines an interior vacuum chamber 44. The vacuum box 42 is located such that a vacuum is applied from below the gap 32, i.e., adjacent the bead 34 of liquid coating. In the illustrated embodiment, the vacuum box 42 has a rear wall 46 and a front wall 48, which extend upwardly from a lower wall 50. The rear wall 46 is mounted, adjacent an upper end thereof, to the die lower body 16. The front wall 48 extends to within a short distance of the backing roll 30, allowing the substrate 28 to pass without hindrance between an upper end of the wall 48 and the backing roll. Side walls (not shown) close the space between the rear and front walls 46, 48 to define the vacuum chamber 44. The vacuum chamber 44 need not be airtight as only a slight vacuum, e.g., less than 2 inch Hg (50.8 mm Hg), is sufficient to stabilize the coating bead 34. In one embodiment, the vacuum pressure applied to the coating bead 34, i.e., the pressure in the vacuum chamber, is about 1 inch Hg (25.4 mm Hg) or less. In another embodiment, the pressure in the vacuum chamber is about 0.5 inch Hg (12.7 mm Hg) or less.

It will be appreciated that such pressures are much higher than is used in a vacuum deposition process. Conventional vacuum deposition processes apply a charge to particles in a high vacuum to move the particles onto a surface to be coated. In the present process, it is the pressure of the liquid exiting the exit slot 24 which is primarily responsible for causing the coating to travel across the gap, rather than a charge applied to the coating. Indeed, there is no need to apply any charge whatsoever.

The vacuum system 40 includes a vacuum source 52, which applies a vacuum on the vacuum chamber via a vacuum conduit 54. The vacuum source 52 can include a pump or other suitable vacuum producing means capable of generating a slight vacuum.

The coating composition or liquid is supplied to the die 10 from any suitable reservoir 60 (FIG. 1) under pressure, using a conventional pump 62 or other suitable well known device, such as a gas pressure system (not shown). Thus, any suitable device may be utilized to effect the flow of the coating material through the inlet 20 into the manifold 22 and out of the extrusion slot 24. Typical pump devices include, for example, gear pumps, centrifugal pumps, and the like. For example, a high precision gear pump with a variable pump speed allows controlled variation of the flow rate and hence the thickness of the coating. If desired, any suitable filter and mixing device may be employed to combine the coating material component and to strain out undesirable agglomerated particles and the like.

While not fully understood, it is believed that the coating liquid which is conventionally applied in the form of a thin film 26 to the substrate 28, has a thin boundary layer of air (not shown) which tends to destabilize the upstream coating meniscus of the bead 34. Applying vacuum to the coating bead 34 assists in stabilizing the coating 26. Stabilizing the coating in this way allows for the coating of thinner layers than has conventionally been possible with a gravure coating process. For example, the minimum thickness of the coating, after drying, can be reduced by from about 10% to about 45%, as compared with a coating formed without applied vacuum, depending on the solids level and line speed. Cross web and down web adhesion also tend to be improved using the applied vacuum.

The vacuum box reduces the amount of solvent evaporation to the atmosphere. In addition to reducing hazards posed by airborne solvents to operators, better uniformity tends to be achieved due to more consistent evaporation rates. Additionally, roll to roll consistency can be improved. Wastage of coating components is thereby reduced.

The coating liquid composition comprising a film forming polymer in a suitable fugitive solvent is applied to a substrate 28 with a slot or extrusion die 10. In one embodiment, the coating liquid preferably comprises an adhesive coating composition. It is applied to a substrate, such as a substrate coated with a hole blocking layer, to produce, when subsequently coated with other imaging layers, a photoreceptor.

The adhesive coating may comprise any suitable film forming polymers. Typical adhesive materials include, for example, polyacrylates, copolyester resins, polyurethanes, blends of resins and the like.

In this regard, any suitable polyarylate film forming thermoplastic ring compound may be utilized in the adhesive layer. Polyarylates are derived from aromatic dicarboxylic acids and diphenols and their preparation is well known. The preferred polyarylates are prepared from isophthalic or terephthalic acids and bisphenol A. In general, there are two processes that are widely used to prepare polyarylates. The first process involves reacting acid chlorides, such as isophthaloyl and terephthaloyl chlorides, with diphenols, such as bisphenol A, to yield polyarylates. The acid chlorides and diphenols can be treated with a stoichiometric amount of an acid acceptor, such as triethylamine or pyridine. Alternatively, an aqueous solution of the dialkali metal salt of the diphenols can be reacted with a solution of the acid chlorides in a water-insoluble solvent such as methylene chloride, or a solution of the diphenol and the acid chlorides can be contacted with solid calcium hydroxide with triethylamine serving as a phase transfer catalyst. The second process involves polymerization by a high-temperature melt or slurry process. For example, diphenyl isophthalate or terephthalate is reacted with bisphenol A in the presence of a transition metal catalyst at temperatures greater than 230° C. Since transesterification is a reversible process, phenol, which is a by-product, must be continually removed from the reaction vessel in order to continue polymerization and to produce high molecular weight polymers. Various processes for preparing polyarylates are disclosed in “Polyarylates,” by Maresca and Robeson in Engineering Thermoplastics, James Margolis, ed., New York: Marcel Dekker, Inc. (1985), pages 255-259, which is incorporated herein by reference as well as the articles and patents disclosed therein which describe the various processes in greater detail.

A typical polyarylate has repeating units represented in the following formula: 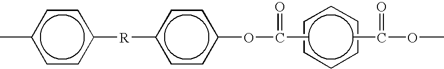
wherein R is C1-C6 alkylene, preferably C3. These polyarylates have a weight average molecular weight greater than about 5,000 and preferably greater than about 30,000. The preferred polyarylate polymers have recurring units of the formula:

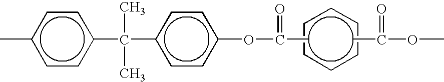

The phthalate moiety may be from isophthalic acid, terephthalic acid or a mixture of the two at any suitable ratios ranging from about 99 percent isophthalic acid and about 1 percent terephthalic acid to about 1 percent isophthalic acid and about 99 percent terephthalic acid, with a preferred mixture being between about 75 percent isophthalic acid and about 25 percent terephthalic acid and optimum results being achieved with between about 50 percent isophthalic acid and about 50 percent terephthalic acid. The polyarylates Ardel from Amoco and Durel from Celanese Chemical Company are preferred polymers. The most preferred polyarylate polymer is available from the Amoco Performance Products under the tradename Ardel D-100. Ardel is prepared from bisphenol-A and a mixture of 50 mol percent each of terephthalic and isophthalic acid chlorides by conventional methods. Ardel D-100 has a melt flow at 375° C. of 4.5 g/l 0 minutes, a density of 1.21 Mg/m3, a refractive index of 1.61, a tensile strength at yield of 69 MPa, a thermal conductivity (k) of 0.18 W/m° K. and a volume resistivity of 3×1016 ohm-cm. Durel is an amorphous homopolymer with a weight average molecular weight of about 20,000 to 200,000. Different polyarylates may be blended in the compositions of the development. Suitable polyarylates also include these disclosed in U.S. Pat. Nos. 6,699,850 and 5,492,785, the entire disclosures of which are incorporated herein by reference.

Alternatively, the adhesive coating may comprise a copolyester resin. A copolyester resin is a linear saturated copolyester reaction product of four diacids and ethylene glycol. The molecular structure of this linear saturated copolyester in which the mole ratio of diacid to ethylene glycol in the copolyester is 1:1. The diacids are terephthalic acid, isophthalic acid, adipic acid and azelaic acid. The mole ratio of terephthalic acid to isophthalic acid to adipic acid to azelaic acid is 4:4:1:1. A representative linear saturated copolyester adhesion promoter of this structure is commercially available as 49,000 (available from Rohm and Haas Inc., previously available from Morton International Inc.). The 49,000 is a linear saturated copolyester which consists of alternating monomer units of ethylene glycol and four randomly sequenced diacids in the above indicated ratio and has a weight average molecular weight of about 70,000. This linear saturated copolyester has a T_{g} of about 32° C. Another preferred representative polyester resin is a copolyester resin derived from a diacid selected from the group consisting of terephthalic acid, isophthalic acid, and mixtures thereof and diol selected from the group consisting of ethylene glycol, 2,2-dimethyl propanediol and mixtures thereof; the ratio of diacid to diol being 1:1, where the T_{g} of the copolyester resin is between about 50° C. and about 80° C. Typical polyester resins are commercially available and include, for example, VITEL PE-100, VITEL PE-200, VITEL PE-200D, and VITEL PE-222, VITEL 1750B all available from Bostik, Inc. More specifically, VITEL PE-100 polyester resin is a linear saturated copolyester of two diacids and ethylene glycol where the ratio of diacid to ethylene glycol in this copolyester is 1:1. The diacids are terephthalic acid and isophthalic acid. The ratio of terephthalic acid to isophthalic acid is 3:2. The VITEL PE-100 linear saturated copolyester consists of alternating monomer units of ethylene glycol and two randomly sequenced diacids in the above indicated ratio and has a weight average molecular weight of about 50,000 and a T_{g} of about 71° C.

Another polyester resin is VITEL PE-200 available from Bostik, Inc. This polyester resin is a linear saturated copolyester of two diacids and two diols where the ratio of diacid to diol in the copolyester is 1:1. The diacids are terephthalic acid and isophthalic acid. The ratio of terephthalic acid to isophthalic acid is 1.2:1. The two diols are ethylene glycol and 2,2-dimethyl propane diol. The ratio of ethylene glycol to dimethyl propane diol is 1.33:1. The VITEL PE-200 linear saturated copolyester consists of randomly alternating monomer units of the two diacids and the two diols in the above indicated ratio and has a weight average molecular weight of about 45,000 and a T_{g} of about 67° C.

The diacids from which the polyester resins of this disclosure are derived are terephthalic acid, isophthalic acid, adipic acid and/or azelaic acid acids only. Any suitable diol may be used to synthesize the polyester resins employed in the adhesive layer of this disclosure. Typical diols include, for example, ethylene glycol, 2,2-dimethyl propane diol, butane diol, pentane diol, hexane diol, and the like.

Any suitable solvent may be utilized to form an adhesive layer coating solution. Typical solvents include, for example, tetrahydrofuran, toluene, hexane, methyl ethyl ketone, isopropanol, methanol, cyclohexane, cyclohexanone, heptane, methylene chloride, chlorobenzenes, other chlorinated solvents, and the like, and mixtures thereof.

Drying of the deposited coating may be effected by any suitable conventional technique such as oven drying, infra red radiation drying, air drying, or the like.

The adhesive layer should be continuous. Satisfactory results are achieved when the adhesive layer has a thickness between about 0.01 micrometer and about 0.2 micrometers after drying. Preferably, the dried thickness is between about 0.03 micrometer and about 1 micrometer. At thicknesses of less than about 0.01 micrometer, the adhesion between the charge generating layer and the blocking layer is poor and delamination can occur when the photoreceptor belt is transported over small diameter supports such as rollers and curved skid plates. When the thickness of the adhesive layer of this disclosure is greater than about 2 micrometers, excessive residual charge buildup is observed during extended cycling.

The extrusion process with applied vacuum may be employed to coat the surface of substrates of various configurations including webs, sheets, plates, and the like. The substrate may be flexible, uncoated, or precoated, as desired. The substrate may comprise a single layer or be made up of multiple layers. The substrate may be insulating or conductive and, if desired, precoated with layers such as conductive layers or a hole blocking layer. Subsequent to coating of the adhesive layer, additional photoconductive layers such as charge generating layers, charge blocking layers, and the like can be applied. These layers are conventional and well known in the art of electrostatography and described for example in U.S. Pat. No. 4,265,990 and U.S. Pat. No. 4,439,507, the entire disclosures of these patents being incorporated herein by reference.

The coating application system is particularly suited to the formation of an adhesive interface layer of a photoreceptor, such as an active matrix (AMAT) photoreceptor. In one embodiment, the system is used to form an interface layer comprising a film forming polymer by applying a coating liquid comprising the film forming polymer in a suitable solvent to a charge blocking layer, such as a silane layer of a photoreceptor or to a conductive layer of a photoreceptor, where no charge blocking layer is used.

Exemplary film forming polymers for the adhesive layer include ARDEL POLYARYLATE (U-100), available from Yuniehkia polyester resins, such as VITEL PE-100™, VITEL PE-200™, VITEL PE-200D™, and VITEL PE-222.TM., available from Bostik, polyester from Rohm and Hass, polyvinyl butyral, and the like.

In one specific embodiment, a solution comprising an ARDEL™ polyarylate dissolved in a solvent, such as a solvent mixture of tetrahydrofuran, monochlorobenzene, and methylene chloride, in a ratio of about 80/10/10 at a solids level of less than about 1 wt % is formed. The solution is fed to an extrusion slot die 12 and applied wet as a thin layer 26 of from about 7500 Angstroms (Å) to about 50,000 Angstroms (Å) in thickness onto a moving substrate 28 while applying a vacuum to the upstream coating bead 34. This results in a dry layer having a thickness of about 75 Angstroms to about 500 Angstroms.

To achieve coatings of such a low thickness, the slot may have a height of about 0.05 mm to about 0.5 mm. In one embodiment the slot has a height of less than about 0.2 mm and at least 0.1 mm, e.g., about 0.13 mm.

Suitable blocking layers include polyvinylbutyral, organosilanes, epoxy resins, polyesters, polyamides, polyurethanes, fluorocarbon resins, silicone resins polysiloxanes, and the like containing an organo-metallic salt. For example, the blocking layer may comprise a reaction product between a hydrolyzed silane and a thin metal oxide layer formed on an outer surface of an oxidizable metal electrically conductive surface. Other suitable blocking layers include nitrogen containing siloxanes or nitrogen containing titanium compounds, such as trimethoxysilyl propylene diamine, hydrolyzed trimethoxysilyl propyl ethylene diamine, N-beta-(aminoethyl) gamma-amino-propyl trimethoxy silane, isopropyl 4-aminobenzene sulfonyl di(dodecylbenzene sulfonyl) titanate, isopropyl di(4-aminobenzoyl)isostearoyl titanate, isopropyl tri(N-ethylamino-ethylamino) titanate, isopropyl trianthranil titanate, isopropyl tri(N,N-dimethyl-ethylamino) titanate, titanium-4-amino benzene sulfonate oxyacetate, titanium 4-aminobenzoate isostearate oxyacetate, [H₂N(CH₂)₄]CH₃ Si(OCH₃)₂ (gamma-aminobutyl) methyl diethoxysilane, and [H₂N(CH₂)₃]CH₃ Si(OCH₃)₂ (gamma-aminopropyl) methyl diethoxysilane, as disclosed in U.S. Pat. Nos. 4,338,387, 4,286,033 and 4,291,110, which are incorporated herein in their entireties by reference. Other suitable charge blocking layer polymer compositions are also described in U.S. Pat. No. 5,244,762, the disclosure of which is incorporated herein in its entirety by reference. These include vinyl hydroxyl ester and vinyl hydroxy amide polymers wherein the hydroxyl groups have been partially modified to benzoate and acetate esters that modified polymers are then blended with other unmodified vinyl hydroxy ester and amide unmodified polymers. An example of such a blend is a 30 mole percent benzoate ester of poly (2-hydroxyethyl methacrylate) blended with the parent polymer poly (2-hydroxyethyl methacrylate). Still other suitable charge blocking layer polymer compositions are described in U.S. Pat. No. 4,988,597, the disclosure of which is incorporated herein by reference in its entirety. These include polymers containing an alkyl acrylamidoglycolate alkyl ether repeat unit. An example of such an alkyl acrylamidoglycolate alkyl ether containing polymer is the copolymer poly(methyl acrylamidoglycolate methyl ether-co-2-hydroxyethyl methacrylate).

In addition to an adhesive interface layer and optionally a charge blocking layer, a photoreceptor may also include a conductive layer, on which the charge blocking layer is optionally formed, a charge transport layer and a charge generating layer. Alternatively, the charge transport layer may be combined with the charge generating layer as a single layer. The interface layer spaces the conductive layer and/or charge blocking layer, where used, from at least one of the charge transport layer and charge generating layer (or combined charge generating and charge transport layer). In one embodiment, the interface layer has one side in direct contact with the charge blocking layer and the opposed side in direct contact with the charge generating layer.

The charge generating layer may comprise a dispersion of finely divided photoconductive organic particles in a solution of a film forming binder. Generally, the coating composition for forming such a layer comprises finely divided photoconductive organic or inorganic particles dispersed in a solution of a film forming polymer dissolved in a liquid solvent for the polymer. Typical organic photoconductive particles include, for example, various phthalocyanine pigments, such as the X-form of metal free phthalocyanine, metal phthalocyanines such as hydroxy gallium phthalocyanine, titanyl phthalocyanine, vanadyl phthalocyanine and copper phthalocyanine; peryienes such as benzimidazole perylene; quinacridones; dibromo anthanthrone pigments; substituted 2,4-diamino-triazines; polynuclear aromatic quinones; and the like and mixtures thereof.

The charge transport layer may comprise any suitable transparent organic polymer or non-polymeric material capable of supporting the injection of photogenerated holes and electrons from the charge generating layer and allowing the transport of these holes or electrons through the organic layer to selectively discharge the surface charge. The active charge transport layer not only serves to transport holes or electrons, but also protects the charge generation layer from abrasion or chemical attack and therefore extends the operating life of the photoreceptor imaging member. The charge transport layer should exhibit negligible, if any, discharge when exposed to a wavelength of light useful in the electrostatographic process for which the photoreceptor is employed. Therefore, the charge transport layer is substantially transparent to radiation in a region in which the photoconductor is to be used. Thus, the active charge transport layer is a substantially non-photoconductive material which supports the injection of photogenerated holes from the generation layer. The charge transport layer in conjunction with the generation layer is a material which is an insulator to the extent that an electrostatic charge placed on the transport layer is not conducted in the absence of illumination.

The active charge transport layer may comprise any suitable activating compound useful as an additive dispersed in electrically inactive polymeric materials making these materials electrically active. These compounds may be added to polymeric materials which are incapable of supporting the injection of photogenerated holes from the generation layer and incapable of allowing the transport of these holes therethrough. This will convert the electrically inactive polymeric material to a material capable of supporting the injection of photogenerated holes from the generation layer and capable of allowing the transport of these holes through the active layer in order to discharge the surface charge on the active layer.

An exemplary charge transport layer comprises at least one charge transporting aromatic amine compound and a polymeric film forming resin in which the aromatic amine is soluble. The substituents should be free from electron withdrawing groups such as NO₂ groups, CN groups, and the like. Any suitable inactive resin binder soluble in methylene chloride, chlorobenzene or other suitable solvent may be employed. Typical inactive resin binders include polycarbonate resin, polyvinylcarbazole, polyester, polyarylate, polyacrylate, polyether, polysulfone, and the like.

One or more of the layers which make up a photoreceptor may be formed with the coating application system described herein. For one or more of the layers applied with the coating application system, the vacuum source may be switched off such that no vacuum is applied to the coating bead.

Any suitable rigid material may be utilized for the extrusion die. Typical rigid materials include, for example, stainless steel, chrome plated steel, ceramics, or any other rigid metal or plastic capable of maintaining precise machining tolerances. Stainless steel and plated steel having a nickel plated intermediate coating and a chrome plated outer coating are preferred because of their long wear characteristics and capability of maintaining precise machining tolerances. The die body may comprise separate top and bottom sections. To achieve the extremely precise coating thickness profiles and exceptional surface quality requirements desired for electrophotographic imaging member coatings, the finish grinding of the dies should be accomplished consistently under high tolerance constraints across the entire die width, e.g. widths as high as 122 cm (48 inches).

Any suitable and conventional technique may be utilized to fabricate the dies of this disclosure. Typical fabrication techniques are described in U.S. Pat. No. 6,057,000. Typical fastening and alignment techniques are illustrated in U.S. Pat. No. 4,521,457 and U.S. Pat. No. 5,614,260, the entire disclosures thereof being incorporated herein by reference. If desired, adjustments to the cross-sectional area of the extrusion slot as well as the manifold cavity of a multi section die may be accomplished by any suitable device such as shims, and the like.

The die lip length varies with the specific coating materials and the proportions thereof employed as well as the slot width and height (determines thickness of ribbon-like extrudate) as well as the coating flow rate. Extrusion passageway (slot) width dimension, slot height, and the like generally depend upon factors such as the coating fluid viscosity, flow rate, distance to the surface of the support member, relative movement between the die and the substrate to be coated, the thickness of the coating desired, and the like. Generally, satisfactory results may be achieved with a narrow passageway 18 and exit slot heights between about 0.1 mm and about 0.75 mm. It is believed, however, that heights greater than 750 micrometers will also provide satisfactory results for some coatings. Optimum control of coating uniformity is achieved with slot heights between about 0.1 mm and about 0.2 mm. In one embodiment, the internal dimensions for an extrusion die includes a die width of about 346 millimeters, a feed channel of about 4.76 millimeters, a manifold cavity diameter of about 4.76 mm at the inlet tapering to a diameter of 1.8 mm at the two opposite ends of the manifold cavity, a slot height of about 0.13 mm, and a slot width of 346 mm.

Generally, the substrate to be coated is a moving substrate and the extrusion die is normally stationary. However, if desired, the substrate can be maintained stationary and the extrusion die and vacuum box can be moved. Alternatively, the substrate and the extrusion die/vacuum box can be moved to achieve relative motion between the extrusion die and the substrate. Relative speeds between the coating die assembly and the surface of the substrate of up to about 100 feet per minute have been tested. However, it is believed that greater relative speeds may be utilized if desired. The relative speed should be controlled in accordance with the flow velocity of the ribbon-like stream of coating material. Higher speeds allow for lower minimum dry coating thicknesses.

The supporting substrate may be opaque or substantially transparent and may be fabricated from various materials having the requisite mechanical properties. The supporting substrate may comprise electrically non-conductive or conductive inorganic or organic composition materials. In specific embodiments, the supporting substrate is in the form of an endless flexible belt and comprises a commercially available biaxially oriented polyester such as PET (polyethylene terephthalate) or PEN (polyethylene naphthalate) available from Dupont Teijin Films, or MELINE™ available from ICI. Exemplary electrically non-conducing materials known for this purpose include polyesters, polycarbonates, polyamides, polyurethanes, and the like.

The average thickness of the supporting substrate depends on numerous factors, including economic considerations. A flexible belt may be of substantial thickness, for example, over 0.2 mm, or have a minimum thickness less than 0.05 mm, provided there are no adverse affects on the final photoreceptor device. In one flexible belt embodiment, the average thickness of the support layer ranges from about 0.065 mm to about 0.15 mm, and specifically from about 0.075 mm to about 0.125 mm for optimum flexibility and minimum stretch when cycled around small diameter rollers, for example, 12 mm diameter rollers.

The gap distance 32 between the die outer lip surface 70 adjacent the exit slot of the passageway and the surface of the substrate to be coated is determined by variables such as viscosity of the coating material, the velocity of the coating substrate and coating thickness. Generally speaking, a smaller gap is desirable for thinner coating thickness. Regardless of the technique employed, the flow rate and distance should be regulated to avoid splashing, dripping, or puddling of the coating material. Typically, the exit slot of the die is positioned from about 0.05 mm to about 0.2 mm from the electrophotographic imaging member substrate during coating. In one embodiment, the gap is from about 0.08 mm to about 0.15 mm. Since the slot coating is generally a premetered coating, the coating thickness is determined by flow rate at the die inlet 20.

Generally, lower coating composition viscosities tend to form thinner wet coatings whereas coating compositions having high viscosities tend to form thicker wet coatings. Obviously, the thickness of a wet coating will be greater than the thickness of a dried coating.

Any suitable temperature may be employed in the coating deposition process. Generally, ambient temperatures are preferred for deposition of solution coatings. However, higher temperatures may be desirable to facilitate more rapid drying of deposited coatings.

Thus, the coating application system allows extrusion coating of coating compositions to form a dried coating having a uniform thickness with fewer defects. The application system enables a photoreceptor to be formed which does not produce undesirable artifacts in the final electrophotographic copy.

The following examples describe exemplary embodiments of the present development. These examples are merely illustrative, and in no way limit the present disclosure to the specific materials, conditions or process parameters set forth therein. All parts and percentages are by weight unless otherwise indicated.

### EXAMPLES

In Examples 1-5, a high precision slot die is used to apply an interface layer on a blocking layer silane. The coating composition comprises an Ardel™ polyacrylate, such as Ardel™ D1100 from Toyota Hsutsu. The polyarylate is dissolved in a tetrahydrofuran (THF)/monochlorobenzene (MCB)/methylene chloride 60/30/10 solvent mixture at a solids level of less than 1 wt. %. This solution is fed by a high precision gear pump through the slot die and applied wet as a thin layer of from about 7500 Å to about 50,000 Å onto a moving substrate. This results in a dry layer of from about 75 Å to about 500 Å. In some Examples, a vacuum of less than 0.9 mm Hg is applied to the upstream coating bead to achieve better coating stability.

### Example 1

A coating composition comprising 0.3 wt % Ardel™ polymer is applied at 30.5 meters per minute using a pump output of 128 cc/min, a die with a 410 mm outlet slot, and a 0.127 mm slot height. A gap of 0.114 mm is provided between the slot and the substrate. No vacuum is applied to the coating bead. The coating quality is at least as good as that produced by a gravure process. The minimum thickness of the coating is 340 Å without vacuum.

### Example 2

A coating composition is applied as for Example 1 but with a vacuum of 0.75 mm Hg applied to the coating bead. The coating quality is at least as good as that produced by a gravure process. The minimum dry thickness of the coating is 320 Å with vacuum.

### Example 3

A coating composition comprising 0.2 wt % Ardel™ polymer is applied at 21.3 meters per minute using a pump output of 51 cc/min, a die with a 410 mm outlet slot, and a 0.127 mm slot height. A gap of 0.114 mm is provided between the slot and the substrate. No vacuum is applied to the coating bead. The coating quality is excellent. The minimum dry thickness of the coating is 180 Å without vacuum.

### Example 4

A coating composition is applied as for Example 3 but with a vacuum of 0.75 mm Hg applied to the coating bead. The coating quality is at least as good as that produced by a gravure process. The minimum dry thickness of the coating is 140 Å with vacuum.

### Example 5

The effect of line speed and solids concentration (polymer wt. %) on the minimum dry coating thickness (in Angstroms) which can be achieved with vacuum 0.75 mm Hg and without vacuum is demonstrated in TABLE 1. As can be seen, the line speed and solids concentration both affect the minimum coating thickness which can be achieved. Applying vacuum reduces the minimum dry thickness which can be achieved by 10 to 45%, depending on the solids level and line speed.

TABLE 1

| Line | Solids Concentration (wt. %) | | | | | |
|---|---|---|---|---|---|---|
| speed | 0.75 | | | | 0.2 | |
| (meters | (w/out | 0.75 | 0.3 (w/out | 0.3 | (w/out | 0.2 |
| per min) | vacuum) | (w/vacuum) | vacuum) | (w/vacuum) | vacuum) | (w/vacuum) |
| 21.3 | 700 | 600 | 190 | 165 | 180 | 106 |
| 24.4 | 750 | 725 | | | | |
| 25.9 | 880 | 700 | 325 | 200 | 180 | 120 |
| 30.5 | 1150 | 870 | 340 | 319 | 160 | 140 |

### Example 6

A coating composition is applied as for Example 2, but with a solvent mixture of THF/MCB/methylene chloride of 80/10/10. The increased THF and lowered MCB improves the quality of the film as compared with a 60/30/10 solvent mixture.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A coating application system for applying an adhesive coating to a photoreceptor substrate comprising:
a coating applicator having an outlet through which a stream of an adhesive liquid coating is delivered;
a photoreceptor substrate which receives the stream of the adhesive liquid coating; and
a vacuum system which applies a vacuum to the adhesive liquid coating.

2. The coating application system according to claim 1, wherein the substrate is spaced from the outlet of the coating applicator by a gap.

3. The coating application system according to claim 2, wherein the gap is at least 0.08 mm.

4. The coating application system according to claim 1, wherein the substrate moves relative to the applicator outlet.

5. The coating application system according to claim 1, wherein the vacuum source includes a housing which defines an interior chamber, the interior chamber being positioned to apply a vacuum to the liquid coating.

6. The coating application system according to claim 5, wherein the vacuum system further includes a vacuum source fluidly connected with the interior chamber for applying a vacuum to the chamber.

7. The coating application system according to claim 1, wherein the vacuum source is configured to apply a vacuum to an upstream end of a coating as it forms on the substrate.

8. The coating application system according to claim 1, wherein the vacuum source is configured to apply a vacuum to a bead of coating liquid on the substrate at an upstream end of the coating.

9. The coating application system according to claim 1, wherein the coating applicator includes a slot extrusion die.

10. A coating process for applying an adhesive coating to a photoreceptor substrate comprising:
delivering a stream of an adhesive coating composition from an outlet;
depositing the stream onto a photoreceptor substrate to form an adhesive coating; and
applying a vacuum to an upstream end of the coating to form a thin and uniform layer.

11. The coating process according to claim 10, wherein the vacuum is applied during delivery of the stream of coating liquid onto the substrate.

12. The coating process according to claim 10, wherein the vacuum is applied to a bead of coating liquid which forms at the upstream end of the coating.

13. The process according to claim 10, further comprising:
moving the substrate relative to the outlet.

14. The process according to claim 10, wherein the vacuum applied is less than 50.8 mm Hg.

15. The process according to claim 10, wherein the vacuum applied is less than 25.4 mm Hg.

16. The process according to claim 10, wherein the step of applying a vacuum includes housing the upstream end of the coating in an evacuated chamber.

17. The process according to claim 10, wherein the outlet is spaced from the substrate by a gap of at least 0.08 mm.

18. The process according to claim 10, wherein the coating composition includes a film forming polymer dissolved in a solvent.

19. The process according to claim 19, wherein the film forming polymer is at a concentration of less than 1 wt % in the coating composition.

20. A coating application system for applying an adhesive layer to a flexible substrate of an electrophotographic imaging member comprising:
a coating applicator having an outlet through which a stream of a liquid adhesive coating is delivered;
means for supporting an associated moving substrate a spaced distance from the outlet, the substrate receiving the stream of liquid adhesive coating; and
a vacuum system which applies a vacuum to the liquid adhesive coating.
